(19) United States
(12) Patent Application Publication
(10) Pub. No.: US 2018/0040947 A1
(43) Pub. Date: Feb. 8, 2018

(54) IC INDUCTOR HAVING SPACE FOR RECEIVING ELECTRIC PART

(71) Applicant: Mag. Layers ScientificTechnics Co. , Ltd., Taoyuan Hsien (TW)

(72) Inventors: Chin Feng CHENG, Taoyuan Hsien (TW); Jui Fong CHIEN, Taoyuan Hsien (TW); Shu Lin CHEN, Taoyuan Hsien (TW)

(21) Appl. No.: 15/227,991

(22) Filed: Aug. 4, 2016

(51) Int. Cl. H01Q 1/42; H01Q 11/14; H01Q 7/00; H01L 23/66; H01L 23/04

(52) U.S. Cl. CPC H01Q 1/42; H01L 23/66; H01L 23/04; H01Q 7/00; H01Q 11/14; H01L 2223/6677; H01L 2223/6672

(57) ABSTRACT

An IC inductor includes a housing having two legs, two conductors attached to the legs of the housing respectively, and an antenna device received and engaged in the housing, and the antenna device includes a conductive extension engaged in one of the legs of the housing and electrically connected to one of the conductors, and another conductive extension is engaged in the other leg of the housing and electrically connected to the other conductor. The housing includes a space formed between the legs for receiving the other electrical parts or elements. The antenna device includes two coils engaged in the housing, and the conductive extensions are extended from the coils respectively.

### BACKGROUND OF THE INVENTION

1. Field of the Invention The present invention relates to an integrated circuit (IC) inductor, and more particularly to an IC inductor including a space for receiving the other electrical parts or elements and for allowing the volume of the circuit board and the electrical facility to be suitably decreased.

2. Description of the Prior Art

Various kinds of typical inductors have been frequently formed in integrated circuits, and normally comprise a conductive coil formed around a core, and the core may be selected from an insulator or a magnetic core. Magnetic cores result in greater inductance values but are impractical to form in many types of integrated circuit. The inductance value is greatly affected by the number of turns of the coil, where the inductance value is proportional to the square of the number of turns of the coil.

For example, U.S. Pat. No. 5,610,433 to Merrill et al., U.S. Pat. No. 6,833,603 to Park et al., U.S. Pat. No. 7,564,319 to Ding et al., and U.S. Pat. No. 9,214,269 to Samala et al. disclose several of the typical inductors each also comprising a conductive coil formed around a core.

However, normally, the typical inductors have no other spaces or chambers available for receiving the other electrical parts or elements such that the volume of the circuit board and the electrical facility may not be suitably decreased.

The present invention has arisen to mitigate and/or obviate the afore-described disadvantages of the conventional integrated circuit (IC) inductors.

### SUMMARY OF THE INVENTION

The primary objective of the present invention is to provide an IC inductor including a space for receiving the other electrical parts or elements and for allowing the volume of the circuit board and the electrical facility to be suitably decreased.

In accordance with one aspect of the invention, there is provided an IC inductor comprising a housing including a chamber formed therein, and including a first leg and a second leg, a first conductor attached to the first leg of the housing, a second conductor attached to the second leg of the housing, and an antenna device received and engaged in the chamber of the housing, and the antenna device including a first conductive extension engaged in the first leg of the housing and electrically connected to the first conductor, and a second conductive extension engaged in the second leg of the housing and electrically connected to the second conductor. The other electrical parts or elements may be received and disposed between the legs of the housing for allowing the volume of the circuit board and the electrical facility to be suitably decreased.

The housing includes a space formed therein and communicating with the chamber of the housing for defining the first and the second legs and for receiving the other electrical parts or elements and for allowing the volume of the circuit board and the electrical facility to be suitably decreased. The antenna device includes a first coil and a second coil received and engaged in the chamber of the housing, the first conductive extension is extended from the first coil, and the second conductive extension is extended from the second coil.

The first coil includes one or more folds, and includes one or more gaps formed therein. The second coil includes a slot formed therein. The antenna device includes at least one additional coil disposed and engaged between the first and the second coils. The additional coil is preferably parallel to the first and the second coils. The additional coil includes at least one fold. The additional coil includes a gap formed therein.

Further objectives and advantages of the present invention will become apparent from a careful reading of the detailed description provided hereinbelow, with appropriate reference to the accompanying drawings.

### BRIEF DESCRIPTION OF THE DRAWINGS

FIG. 1 is a partial perspective view of an IC inductor in accordance with the present invention for attaching to a circuit board;

FIG. 2 is a partial exploded view illustrating the operation of the IC inductor to the circuit board;

FIG. 3 is a perspective view of the IC inductor;

FIG. 4 is a front plan schematic view of the IC inductor; and

FIG. 5 is a partial exploded view of the IC inductor.

### DETAILED DESCRIPTION OF THE PREFERRED EMBODIMENT

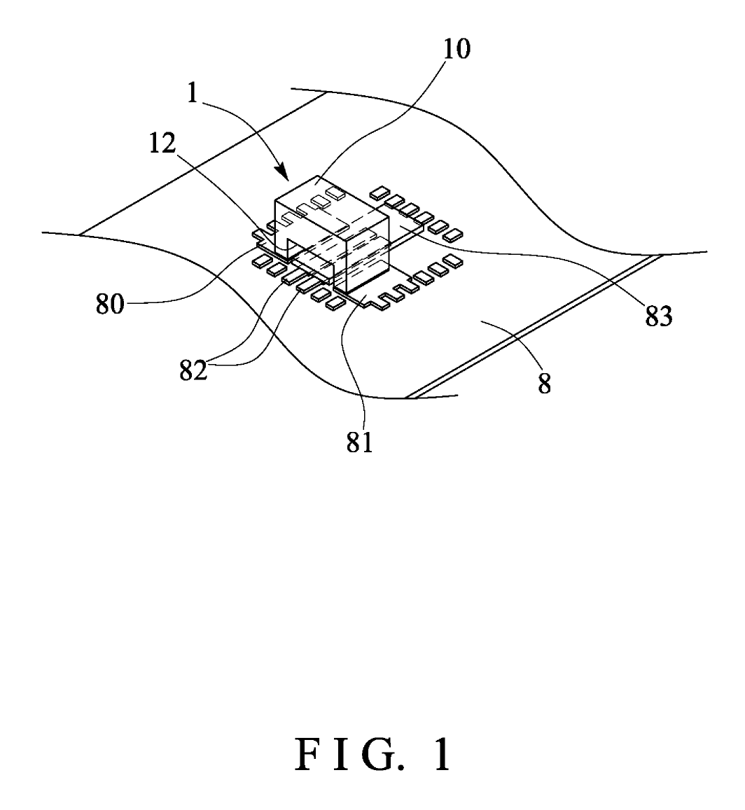

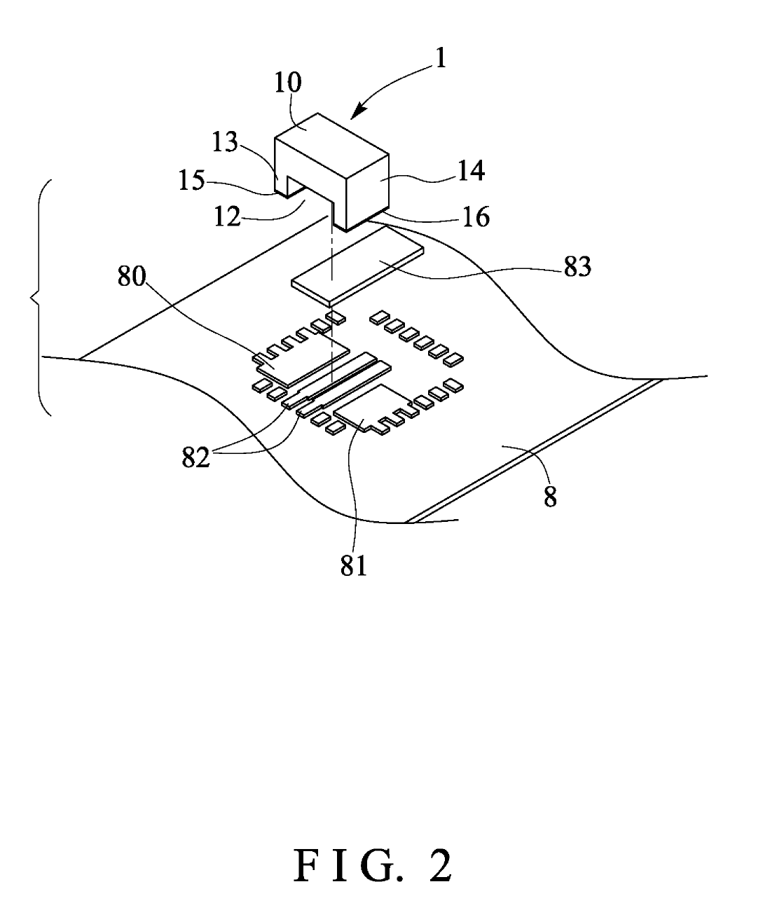

Referring to the drawings, and initially to FIGS. 1 and 2, an integrated circuit (IC) inductor 1 in accordance with the present invention is provided for attaching or mounting or securing to a circuit board 8 which includes a number of terminals or contacts 80, 81, 82 formed or provided thereon, and one or more electrical parts or elements 83 to be disposed or engaged onto the circuit board 8, for example, the electrical element 83 is going to be electrically contacted or engaged with some of the contacts 82.

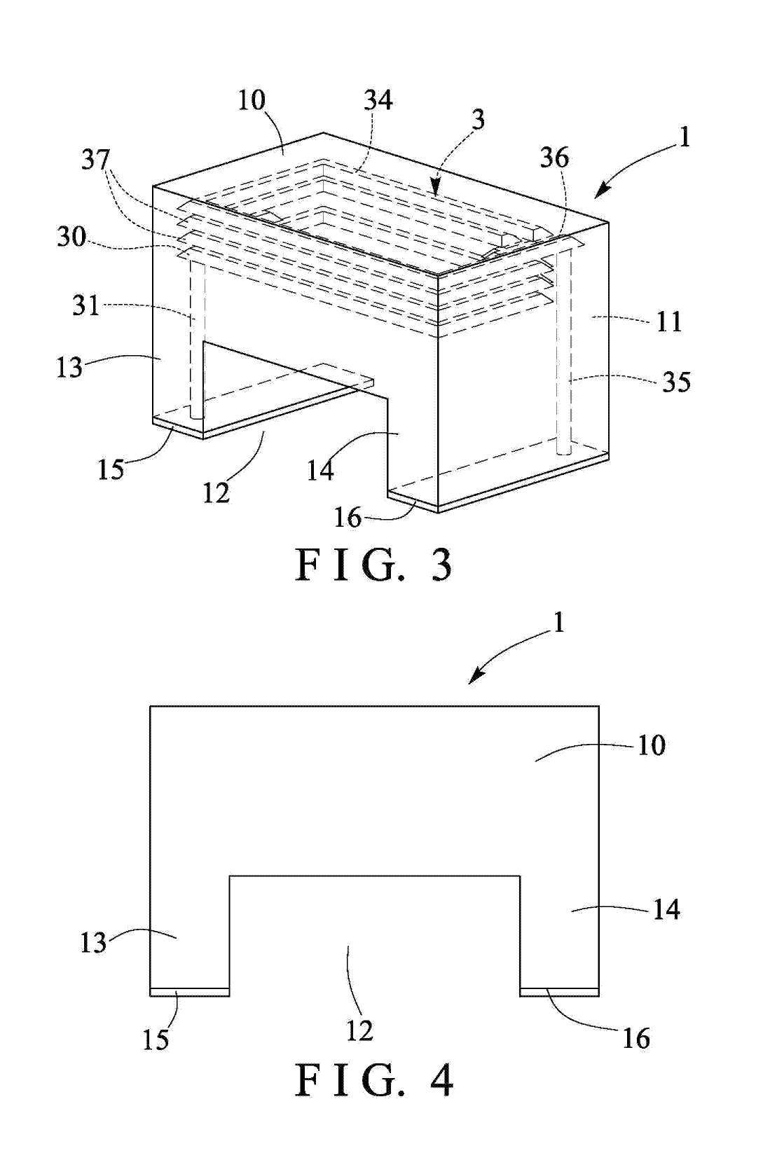

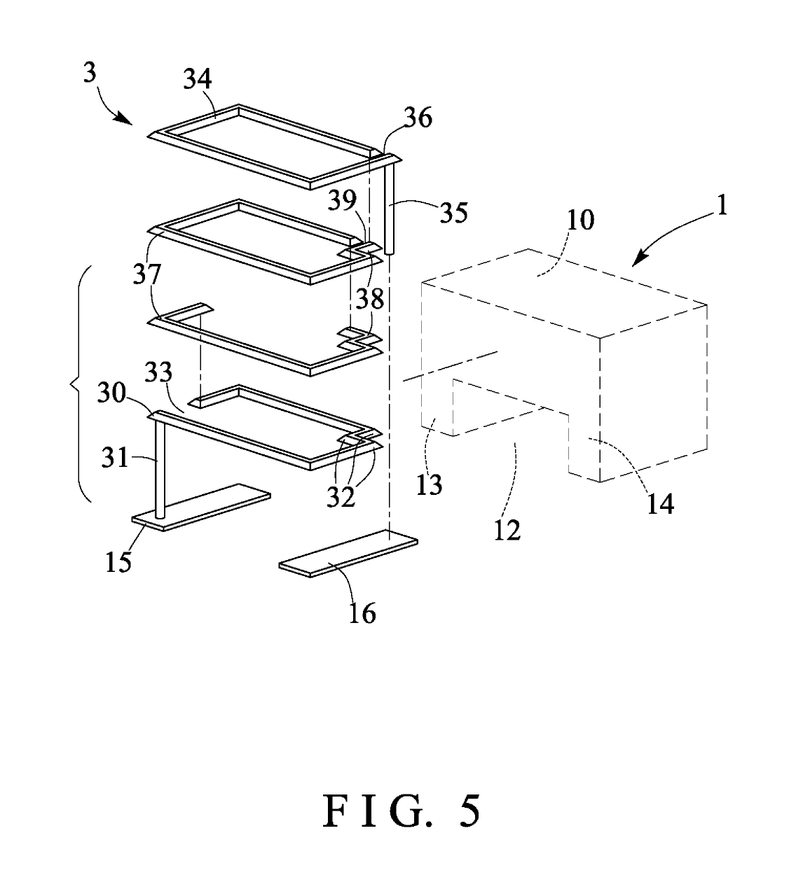

As shown in FIGS. 3-5, the IC inductor 1 in accordance with the present invention comprises an outer receptacle or housing 10 including a compartment or chamber 11 formed therein (FIG. 3) for receiving or engaging with an antenna device 3 therein, and including a substantially cubical or parallelepiped structure or configuration having a compartment or space 12 formed therein and communicating with the chamber 11 of the housing 10 for forming or defining two limbs or legs 13, 14, and two conductors 15, 16 attached or mounted or secured to the legs 13, 14 of the housing 10 respectively.

The antenna device 3 includes a first layer or coil 30 received or engaged in the chamber 11 of the housing 10, a first conductive link or extension 31 extended from the first coil 30 and received or engaged in the first leg 13 of the housing 10, and electrically connected or coupled to the first conductor 15, and the first coil 30 includes a number of bent portions or folds 32 and a gap 33 formed therein, a second layer or coil 34 is also received or engaged in the chamber 11 of the housing 10, a second conductive link or extension 35 extended from the second coil 34 and received or engaged in the second leg 14 of the housing 10, and electrically connected or coupled to the second conductor 16, and the second coil 34 includes a gap or slot 36 formed therein.

The antenna device 3 further includes one or more (such as two) additional layers or coils 37 also received or engaged in the chamber 11 of the housing 10, and disposed or engaged between the first and the second coils 30, 34 and substantially parallel to the first and the second coils 30, 34, and the additional coils 37 each may also include a number of bent portions or folds 38 and a gap 39 formed therein. The electrically connecting or coupling of the first and the second coils 30, 34 with the additional coils 37 is typical and is not related to the present invention and will not be described in further details.

In operation, as shown in FIGS. 1 and 2, the electrical parts or elements 83 may be received or engaged in the space 12 that is formed or defined between the legs 13, 14 of the housing 10 for allowing the volume of the circuit board 8 and the electrical facility or electrical parts or elements 83 and the IC inductor 1 to be suitably decreased.

Accordingly, the IC inductor in accordance with the present invention includes a space for receiving the other electrical parts or elements and for allowing the volume of the circuit board and the electrical facility to be suitably decreased.

Although this invention has been described with a certain degree of particularity, it is to be understood that the present disclosure has been made by way of example only and that numerous changes in the detailed construction and the combination and arrangement of parts may be resorted to without departing from the spirit and scope of the invention as hereinafter claimed.

I claim:

1. An IC inductor comprising:
a housing including a chamber formed therein, and including a first leg and a second leg,
a first conductor attached to said first leg of said housing,
a second conductor attached to said second leg of said housing, and
an antenna device received and engaged in said chamber of said housing, and said antenna device including a first conductive extension engaged in said first leg of said housing and electrically connected to said first conductor, and a second conductive extension engaged in said second leg of said housing and electrically connected to said second conductor.

2. The IC inductor as claimed in claim 1, wherein said housing includes a space formed therein and communicating with said chamber of said housing for defining said first and said second legs.

3. The IC inductor as claimed in claim 1, wherein said antenna device includes a first coil and a second coil received and engaged in said chamber of said housing, said first conductive extension is extended from said first coil, and said second conductive extension is extended from said second coil.

4. The IC inductor as claimed in claim 3, wherein said first coil includes at least one fold.

5. The IC inductor as claimed in claim 3, wherein said first coil includes at least one gap formed therein.

6. The IC inductor as claimed in claim 3, wherein said second coil includes a slot formed therein.

7. The IC inductor as claimed in claim 3, wherein said antenna device includes at least one additional coil disposed and engaged between said first and said second coils.

8. The IC inductor as claimed in claim 7, wherein said at least one additional coil is parallel to said first and said second coils.

9. The IC inductor as claimed in claim 7, wherein said at least one additional coil includes at least one fold.

10. The IC inductor as claimed in claim 7, wherein said at least one additional coil includes a gap formed therein.
